(19) United States
(12) Patent Application Publication
(10) Pub. No.: US 2025/0209604 A1
(43) Pub. Date: Jun. 26, 2025

(54) CROSSTALK CORRECTION FOR IMAGES OF SEMICONDUCTOR SPECIMENS

(71) Applicant: Applied Materials Israel Ltd., Rehovot (IL)

(72) Inventor: Lior AKERMAN, Mazkeret Batya (IL)

(21) Appl. No.: 18/393,570

(22) Filed: Dec. 21, 2023

(51) Int. Cl. G06T 7/00; G06T 5/50; G06T 5/90; G06T 7/12; G06T 7/143

(52) U.S. Cl. CPC G06T 7/0006; G06T 5/50; G06T 5/90; G06T 7/001; G06T 7/12; G06T 7/143; G06T 2207/10061; G06T 2207/20081; G06T 2207/30148

(57) ABSTRACT

There is provided a system and method of examination of a semiconductor specimen. The semiconductor specimen comprises at least a surface layer and a under layer. The method includes obtaining a secondary electron (SE) image and a backscattered electron (BSE) image of the specimen acquired by an electron beam tool, wherein the BSE image possesses one or more image artifacts caused by one or more structural features on the surface layer; processing the SE image to generate a feature mask comprising a set of segments representative of the one or more structural features; and generating a corrected BSE image based on the BSE image and the feature mask, wherein the corrected BSE image possesses suppressed image artifacts with respect to the one or more image artifacts in the BSE image.

### TECHNICAL FIELD

The presently disclosed subject matter relates, in general, to the field of examination of a semiconductor specimen, and more specifically, to image correction for semiconductor specimen examination.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. A variety of non-destructive examination tools includes, by way of non-limiting example, scanning electron microscopes, atomic force microscopes, optical inspection tools, etc.

The manufacturing process of a semiconductor device can include various procedures such as etching, depositing, planarization, growth such as epitaxial growth, implantation, etc. The examination process can include a plurality of examination steps, which can be performed for example after certain process procedures, and/or after the manufacturing of certain layers, or the like. Additionally, or alternatively, each examination step can be repeated multiple times, for example for different wafer locations, or for the same wafer locations with different examination settings.

During the examination processes at various steps during semiconductor fabrication, examination images are acquired by the examination tools which are processed for purpose of examination operations such as detecting and classifying defects on specimens, as well as performing metrology related operations. In some cases, certain image artifacts and/or errors may occur in the examination images, depending on the specific examination modalities. Such image artifacts may lead to an increasing inability to accurately examine and measure critical integrated device dimensions in the semiconductor industry.

### SUMMARY

In accordance with certain aspects of the presently disclosed subject matter, there is provided a computerized system of examination of a semiconductor specimen, the semiconductor specimen comprising at least a surface layer and an underlayer, the system comprising a processing circuitry configured to: obtain a secondary electron (SE) image and a backscattered electron (BSE) image of the specimen acquired by an electron beam tool, wherein the BSE image possesses one or more image artifacts caused by one or more structural features on the surface layer; process the SE image to generate a feature mask comprising a set of segments representative of the one or more structural features; and generate a corrected BSE image based on the BSE image and the feature mask, wherein the corrected BSE image possesses suppressed image artifacts with respect to the one or more image artifacts in the BSE image.

In addition to the above features, the system according to this aspect of the presently disclosed subject matter can comprise one or more of features (i) to (ix) listed below, in any desired combination or permutation which is technically possible:
(i). The processing circuitry can be configured to generate the corrected BSE image by applying a correction factor to the feature mask to obtain a corrected feature mask, and correcting the BSE image using the corrected feature mask.
(ii). The correction factor can be used for minimizing effects of the one or more image artifacts in the BSE image, taking into consideration gray level variations between the SE image and the BSE image.
(iii). The SE image is a topographic image where contours of the structural features on the surface layer are enhanced. The feature mask can be generated by performing image segmentation on the SE image so as to obtain the set of segments as geometrical representation of the structural features.
(iv). The image segmentation can be performed based on one of the following: edge detection, machine learning, a segmentation threshold for the SE image, or design data of the specimen.
(v). The correction factor can be automatically selected by:
   creating a temporary BSE image by applying an initial correction factor to the feature mask to get a temporary correction mask, and correcting the BSE image using the temporary correction mask;
   calculating a gradient energy for pixels of the temporary BSE image that correspond to contour pixels of the SE image; and
   iterating the creating and calculating with a different correction factor until an iteration condition is met, and selecting the correction factor having minimized gradient energy, wherein the selected correction factor, when being used, is expected to result in the suppressed image artifacts in the BSE image.
(vi). The calculation of a gradient energy can comprise generating a binary mask based on the SE image, the binary mask representing contours of the structural features on the surface layer; calculating absolute gradients for pixels of the temporary BSE image that correspond to pixels of the contours in the binary mask; and aggregating the absolute gradients to obtain a gradient energy corresponding to the initial correction factor.
(vii). The correction factor can be automatically selected by:
   selecting a region of interest (ROI) on the BSE image containing an image artifact and a surrounding area of the image artifact, the surrounding area not including any structural feature of the underlayer;
   creating a temporary BSE image by applying an initial correction factor to the feature mask to get a temporary correction mask, and correcting the BSE image using the temporary correction mask;
   calculating, based on the temporary BSE image, a first average gray level (GL) value for pixels in the surrounding area and a second average GL value for pixels belonging to the image artifact;
   computing an absolute difference value between the first and second average GL values, the absolute difference value corresponding to the initial correction factor; and
   iterating the creating, calculating, and computing with a different correction factor until an iteration condition is met, and selecting the correction factor that corresponds to a minimized absolute difference value, wherein the selected correction factor, when being used, is expected to result in the suppressed image artifacts in the BSE image.
(viii). The surface layer can comprise multiple types of structural features. The processing circuitry can be configured to process the SE image to generate multiple feature masks corresponding to the multiple types of structural features, and generate the corrected BSE image by applying respective correction factors to the multiple feature masks to obtain multiple corrected feature masks, and correcting the BSE image using the multiple corrected feature masks.
(ix). The specimen can comprise multiple underlayers at different depths, each underlayer comprising respective structural features captured by the BSE image. The processing circuitry can be configured to generate the corrected BSE image by dividing the BSE image into different regions based on the structural features from different underlayers, applying different correction factors for regions in the feature mask corresponding to the different regions in the BSE image, so as to obtain the corrected feature mask; and correcting the BSE image using the corrected feature mask.

In accordance with other aspects of the presently disclosed subject matter, there is provided a computerized method of examination of a semiconductor specimen, the semiconductor specimen comprising at least a surface layer and an underlayer, the method comprising obtaining a secondary electron (SE) image and a backscattered electron (BSE) image of the specimen acquired by an electron beam tool, wherein the BSE image possesses one or more image artifacts caused by one or more structural features on the surface layer; processing the SE image to generate a feature mask comprising a set of segments representative of the one or more structural features; and generating a corrected BSE image based on the BSE image and the feature mask, wherein the corrected BSE image possesses suppressed image artifacts with respect to the one or more image artifacts in the BSE image.

This aspect of the disclosed subject matter can comprise one or more of features (i) to (ix) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform a method of examination of a semiconductor specimen, the semiconductor specimen comprising at least a surface layer and an underlayer, the method comprising: obtaining a secondary electron (SE) image and a backscattered electron (BSE) image of the specimen acquired by an electron beam tool, wherein the BSE image possesses one or more image artifacts caused by one or more structural features on the surface layer; processing the SE image to generate a feature mask comprising a set of segments representative of the one or more structural features; and generating a corrected BSE image based on the BSE image and the feature mask, wherein the corrected BSE image possesses suppressed image artifacts with respect to the one or more image artifacts in the BSE image.

This aspect of the disclosed subject matter can comprise one or more of features (i) to (ix) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of image correction for a BSE image captured for a semiconductor specimen in accordance with certain embodiments of the presently disclosed subject matter.

FIG. 3 illustrates a generalized flowchart of generating a corrected BSE image in accordance with certain embodiments of the presently disclosed subject matter.

FIG. 4 illustrates a generalized flowchart of one way of automatically selecting the correction factor in accordance with certain embodiments of the presently disclosed subject matter.

FIG. 5 shows a generalized flowchart of another way of automatically selecting the correction factor in accordance with certain embodiments of the presently disclosed subject matter.

FIG. 6 shows a schematic illustration of PE interaction with different layers of an exemplified specimen in accordance with certain embodiments of the presently disclosed subject matter.

FIG. 7 shows an example of SE image and BSE image captured for a region of a specimen in accordance with certain embodiments of the presently disclosed subject matter.

FIG. 8 illustrates an example of a specimen comprising a surface layer and two underlayers, and a corresponding BSE image in accordance with certain embodiments of the presently disclosed subject matter.

FIG. 9 illustrates another example of a SE image, a BSE image and a corrected BSE image in accordance with certain embodiments of the presently disclosed subject matter.

### DETAILED DESCRIPTION OF EMBODIMENTS

The process of semiconductor manufacturing often requires multiple sequential processing steps and/or layers, some of which could possibly cause errors that may lead to yield loss. Examples of various processing steps can include lithography, etching, depositing, planarization, growth (such as, e.g., epitaxial growth), and implantation, etc. Various examination operations, such as defect-related examination (e.g., defect detection, defect review, and defect classification, etc.), and/or metrology-related examination (e.g., critical dimension (CD) measurements, etc.), can be performed at different processing steps/layers during the manufacturing process to monitor and control the process. The examination operations can be performed a multiplicity of times, for example after certain processing steps, and/or after the manufacturing of certain layers, or the like.

As described above, various types of examination tools can be used for performing examination of a semiconductor specimen, such as, e.g., optical inspection tools, electron beam tools, etc. By way of example, scanning electron microscopes (SEM) is a type of electron microscope that produces images of a specimen by scanning the specimen with a focused beam of electrons. SEM is capable of accurately inspecting and measuring features during the manufacture of semiconductor wafers. The electrons interact with atoms in the specimen, producing various signals that contain information on the surface topography and/or composition of the specimen.

Specifically, when an electron beam strikes a specimen, different types of signals are generated. Secondary electrons (SEs) originate from the surface or the near-surface regions of the specimen. They are a result of inelastic interactions between the primary electron beam and the specimen, and have lower energy. SEs are generally emitted from a thin layer (for example 2-3 nm) at a surface of the specimen.

Specifically, SEs are produced when an incident electron excites an electron in the specimen and loses some of its energy in the process. The excited electron moves in all directions, and, if reaching the surface of the specimen before losing all its energy, it escapes from the surface as a secondary electron. The shallow depth (e.g., 2-3 nm) of production of detected SEs makes them ideal for examining topography of the specimen's surface.

In addition to SEs, backscattered electrons (BSEs) are also generated from the scanning of the wafer by the electron beam. BSEs reflect back after elastic interactions between the beam and the specimen. As these electrons are more energetic, they may exit the surface even if generated from deeper within the specimen. They are a result of elastic scattering of electrons with atoms, which result in a change in the electrons' trajectory. Specifically, when the electron beam strikes the specimen, some of the electrons are deflected from their original path by atoms in the specimen in an elastic fashion. These essentially elastically scattered primary electrons (which are high-energy electrons) that rebound within the sample, are referred to as BSEs.

BSEs and SEs can be collected by different detectors of the SEM tool. As described, BSEs come from deeper regions of the sample, while SEs originate from surface regions. Therefore, BSEs and SEs carry different types of information. For instance, images generated based on BSEs show high sensitivity to differences in atomic number, therefore can carry information on the specimen's interior structure and/or composition of underlayers (i.e., this is referred to as the see-through ability of the BSEs to probe the specimen in depth when provided with enough landing energy), whereas images generated based on SEs can provide more detailed surface information.

It is known that when BSEs reach the surface of the specimen, they may also trigger the emission of additional SEs, which are known as SE2 electrons, as opposed to the so called SE1 electrons that are emitted as a result of the primary beam entering the specimen, and generally have very similar traits as the SE1 electrons. The surface emitted SE (i.e., SE1) and additional SE (i.e., SE2) may both be collected by a SE detector, thus affecting the pixel values of the generated SE image. In other words, the pixel values of the SE image are intended to correspond to the surface SEs only. However, due to the impact of the additional SEs, the pixel values of the SE image are undesirably altered, causing the underlayer features to be seen in the SE image. Such crosstalk phenomenon is addressed in U.S. patent application Ser. No. 17/678,744 “Reducing backscattered electron induced errors”, which is incorporated herein by reference in its entirety.

The present disclosure addresses a different type of crosstalk phenomenon between layers, specifically, in cases where the BSE emission is affected by a surface pattern, causing the surface patterns to be visible on a BSE image even when the BSE detectors are designed not to collect SE emission. This is a very complex physical phenomenon related to various factors. One possible cause may relate to the fact that the primary electrons (PEs) of the electron beam, before reaching the underlayer, travel through the surface layer (e.g., a photoresist layer) and incidences on the surface patterns. Due to the incidence with the surface patterns, PEs reach the underlayer at a different landing energy in areas where there are surface patterns on the surface layer with respect to areas where there are no patterns on the surface layer. In addition, since some of the PE energy is lost through the surface features, the PEs reach the underlayer with a different interaction volume, which unavoidably affect the amount of emitted BSEs.

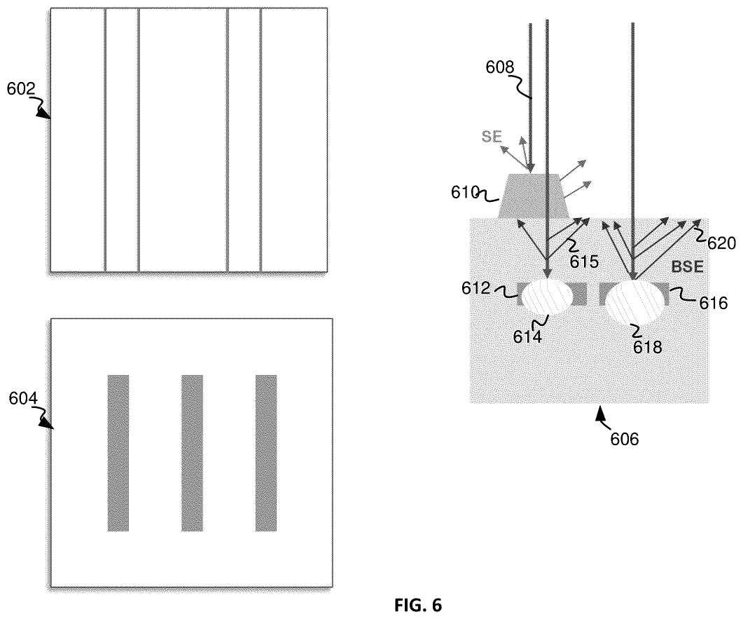

FIG. 6 shows a schematic illustration of PE interaction with different layers of an exemplified specimen in accordance with certain embodiments of the presently disclosed subject matter.

The exemplified specimen has a surface layer and an underlayer. FIG. 6 illustrates an SE image 602 and a BSE image 604 captured for a region of the specimen. The SE image 602 shows two line structures on the surface layer, while the BSE image 604 shows three line structures on the underlayer. A partial cross-sectional view of the specimen is illustrated in 606. As shown, when PEs 608 reach an area of the surface layer where there is a surface line structure 610 and incidences on the line structure, SEs are produced when electrons that are excited by the PEs escape from the surface of the specimen. The PEs 608 have lost some of their energy while traveling through the surface line structure 610 and reach an underlayer line structure 612 with a relatively lower landing energy and a smaller interaction volume 614. BSEs 615 are emitted as a result of elastic scattering of electrons with atoms of the underlayer structure.

On the other hand, when PEs reach an area of the surface layer where there is no surface structure, the PEs do not incidence with any surface structure and reach an underlayer line structure 616 with a relatively higher landing energy and a larger interaction volume 618 (with respect to the interaction volume 614). In such cases, a larger amount of BSEs 620 will be emitted as compared to the emitted BSEs 615. The different amounts of BSEs, collected from the two areas, will result in different signal strengths in the BSE image.

Therefore, the BSE image which was originally intended to reflect the underlayer structure will inevitably also show a representation of the surface patterns on the surface layer (not illustrated in the present example of BSE image 604), which will interfere with the representation of the underlayer structures in the image. In cases where there is an intermediate underlayer between the surface layer and the target underlayer to be imaged, the two populations of PEs (i.e., incidence with the surface patterns or not) reach this intermediate layer at different landing energies and have different interactions with this layer, which further impact the BSEs emitted from the target underlayer. The BSE images resulting as such, when being used for examination processes such as metrology related operations, e.g., CD, overlay, etc., may affect the examination accuracy and cause process errors.

Accordingly, certain embodiments of the presently disclosed subject matter propose to improve the quality of the BSE image by reducing the impact of the surface features on the BSE images. The present disclosure proposes to process the SE image to generate a feature mask comprising a set of segments representative of the structural features on the surface layer, and generating a corrected BSE image based on the BSE image and the feature mask. The corrected BSE image possesses suppressed image artifacts with respect to the one or more image artifacts in the BSE image, as will be detailed below.

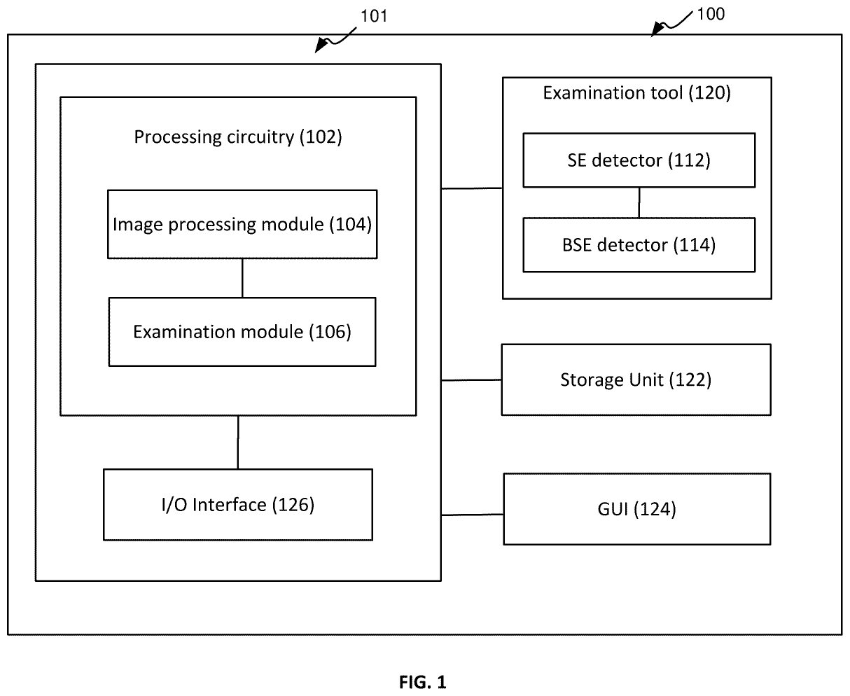

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, nuisance filtration, segmentation, and/or metrology operations, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning, imaging, sampling, reviewing, measuring, classifying, and/or other processes provided with regard to the specimen or parts thereof. The examination tools 120 can be implemented as machines of various types. In some embodiments, the examination tool can be implemented as an electron beam machine/tool, such as e.g., Scanning Electron Microscope (SEM) as described above, Atomic Force Microscopy (AFM), or Transmission Electron Microscope (TEM), etc.

According to certain embodiments, the examination tool 120 can include one or more inspection tools and/or one or more review tools. The inspection tools can scan the specimen to capture inspection images and detect potential defects in accordance with a defect detection algorithm. The output of the detection module is a defect map indicative of defect candidate distribution on the semiconductor specimen. The review tools can be configured to capture review images at locations of the defect candidates in the map, and review the review images for ascertaining whether a defect candidate is indeed a DOI.

In some cases, at least one of the examination tools 120 has metrology capabilities. Such an examination tool is also referred to as a metrology tool. The metrology tool can be configured to generate image data in response to scanning the specimen, and perform metrology operations based on the image data.

In some embodiments, the examination tool can be an electron beam tool, such as an SEM. In such cases, the examination tool 120 comprises one or more SE detectors 112 and one or more BSE detectors 114 for respectively collecting the emitted SEs and BSEs, based on which the corresponding SE image and BSE image are generated.

The resulting image data (the SE and BSE images) can be transmitted—directly or via one or more intermediate systems—to system 101. The present disclosure is not limited to any specific type of examination tools and/or the resolution of image data resulting from the examination tools.

According to certain embodiments of the presently disclosed subject matter, the examination system 100 comprises a computer-based system 101 operatively connected to the examination tools 120 and capable of improving/correcting BSE images obtained during specimen fabrication. System 101 is also referred to as an image correction system.

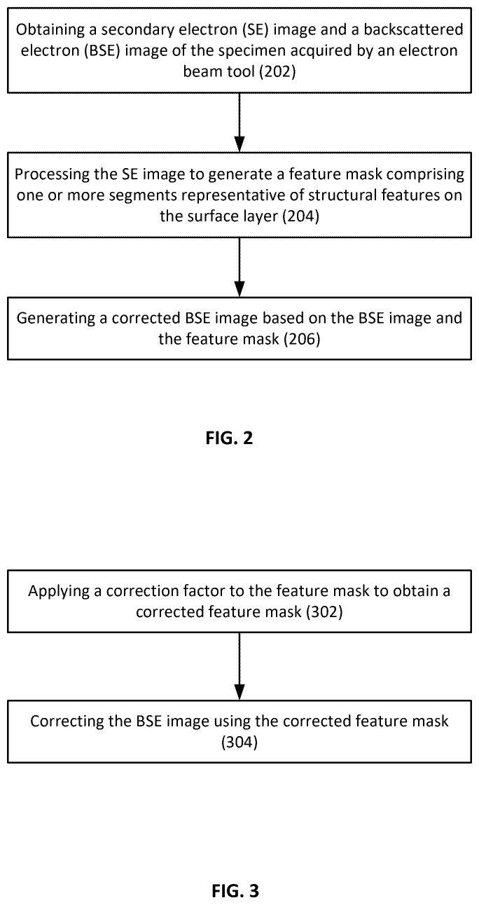

System 101 includes a processing circuitry 102 operatively connected to a hardware-based I/O interface 126 and configured to provide processing necessary for operating the system, as further detailed with reference to FIGS. 2-5. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

One or more functional modules comprised in the processing circuitry 102 of system 101 can include an image processing module 104, and an examination module 106 operatively connected to the image processing module 104.

Specifically, the processing circuitry 102, in particular the image processing module 104, can be configured to obtain, in runtime, via an I/O interface 126, a secondary electron (SE) image and a backscattered electron (BSE) image of a specimen acquired by an electron beam tool, such as the examination tool 120.

The image processing module 104 can be further configured to process the SE image to generate a feature mask comprising one or more segments representative of structural features on the surface layer, and generate a corrected BSE image based on the BSE image and the feature mask. The corrected BSE image possesses reduced/suppressed image artifacts caused by the structural features of the surface layer.

In some cases, optionally, the examination module 106 can be configured to perform additional examination based on the corrected BSE image. Examples of further examination can relate to metrology operations, such as, e.g., CD measurements, overlay, etc. In such cases, the image processing module 104 and examination module 106 can be regarded as part of an examination recipe usable for performing runtime examination operations on acquired runtime images. System 100 can use the examination recipe for performing runtime specimen examination.

Operation of systems 100 and 101, the processing circuitry 102, and the functional modules therein will be further detailed with reference to FIGS. 2-5.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as processing the SE image, generating a corrected BSE image and performing further examination, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of a semiconductor specimen. The one or more examination modules can be implemented as stand-alone computers, or their functionalities (or at least part thereof) can be integrated with the examination tool 120. In some cases, the output of system 101, e.g., the corrected BSE image, and/or further examination result, can be provided to the one or more examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store images of the specimen and/or derivatives thereof produced by the examination tool 120, such as, e.g., the SE and the BSE images as described above. Accordingly, the input data as required can be retrieved from the storage unit 122 and provided to the processing circuitry 102 for further processing. The output of the system 101, such as, e.g., the corrected BSE image, and/or further examination result, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including the images of the specimen, etc. The user may be provided, through the GUI, with options of defining certain operation parameters, such as, e.g., the correction factor, etc. The user may also view the operation results or intermediate processing results, such as, e.g., the corrected BSE image, and/or further examination result, etc., on the GUI.

In some cases, system 101 can be further configured to send, via I/O interface 126, the operation results to the examination tool 120 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp ups, and helps engineers find ways to improve yield. YMS helps semiconductor manufacturers and fabs manage high volumes of production analysis with fewer engineers. These systems analyze the yield data and generate reports. YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tool 120 and the system 101 can be located at the same entity (in some cases hosted by the same device) or distributed over different entities.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tools 120, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools 120 in examination-related processes.

While not necessarily so, the process of operations of systems 101 and 100 can correspond to some or all of the stages of the methods described with respect to FIGS. 2-5. Likewise, the methods described with respect to FIGS. 2-5 and their possible implementations can be implemented by systems 101 and 100. It is therefore noted that embodiments discussed in relation to the methods described with respect to FIGS. 2-5 can also be implemented, mutatis mutandis as various embodiments of the systems 101 and 100, and vice versa.

Referring to FIG. 2, there is illustrated a generalized flowchart of image correction for a BSE image captured for a semiconductor specimen in accordance with certain embodiments of the presently disclosed subject matter.

As described above, a semiconductor specimen is typically made of multiple layers. The examination process of a specimen can be performed a multiplicity of times during the fabrication process of the specimen, for example following certain processing steps of specific layers. Images of the specimen or parts thereof can be acquired at these processing steps/layers to be examined.

For the purpose of illustration only, certain embodiments of the following description are described with respect to an exemplified specimen comprising two layers, e.g., a surface layer and a underlayer (also termed as an under layer, or a sub-surface layer). An underlayer referred to herein can be any layer located beneath the surface layer of the specimen. It can refer to a layer that is immediately underneath the surface layer (e.g., an adjacent layer on which the surface layer deposits), or any layer that is below the surface, but not immediately next to the surface layer.

Those skilled in the art will readily appreciate that the teachings of the presently disclosed subject matter, such as the image correction process described below, can be performed following any layer(s) and/or processing step(s) of the layer(s) of the specimen. The present disclosure should not be limited to the number of layers comprised in the specimen and/or the specific layer(s) to be examined.

When examining a semiconductor specimen that comprises at least a surface layer and a under layer using an electron beam (e-beam) tool, a secondary electron (SE) image and a backscattered electron (BSE) image of the specimen can be acquired (202) by the e-beam tool, such as SEM, as described above. A specimen here can refer to a semiconductor wafer, a die, or parts thereof, that is fabricated and examined in the fab during a fabrication process thereof. An image of a specimen can capture at least part of the specimen to be examined by the tool. By way of example, an image, such as a SE image or a BSE image, can capture a target region or a target structure (e.g., a structural feature or pattern on a semiconductor specimen) that is of interest to be examined on the specimen.

The SE image and BSE image can be provided to the image processing module 104 in processing circuitry 102 for further processing. In some cases, the SE image and the BSE image can be pre-processed by performing, e.g., image smoothing, gradient operations, etc., prior to be sent to the image processing module 104.

As described above, the SE image is originally intended for capturing the surface features on the surface layer, whereas the BSE image is intended for reflecting the underlayer structures. However, due to the crosstalk phenomenon between layers, in particular the impact of the surface features on the BSE emission as described above with reference to FIG. 6, the BSE image often possesses one or more image artifacts caused by one or more structural features on the surface layer. In other words, the surface features are visible (to an extent) on the BSE image even when the BSE detectors are designed not to collect SE emission. It is thus desired to remove, or at least reduce/suppress such image artifacts from the BSE image.

SEs are emitted from a shallow depth (for example 2-3 nm) of the surface layer. SEs that impinge near edges of the surface features may travel near the edge, while staying at a distance of 2-3 nm from the edge along a much longer distance than when they are far from the edges, thus cannot escape from the surface. Due to this nature of the SE emission, the surface features of a surface layer, as imaged by SE detectors, are usually topographic, i.e., edges/contours of the structural features on the surface layer are enhanced in the SE image, such as schematically illustrated in the SE image 602. On the other hand, BSEs are high-energy electrons originating from deeper regions, resulting from interaction with underlayer structures. The BSE image thus presents a geometrical representation of the interacted structural features, such as schematically illustrated in the BSE image 604, rather than a topographic representation.

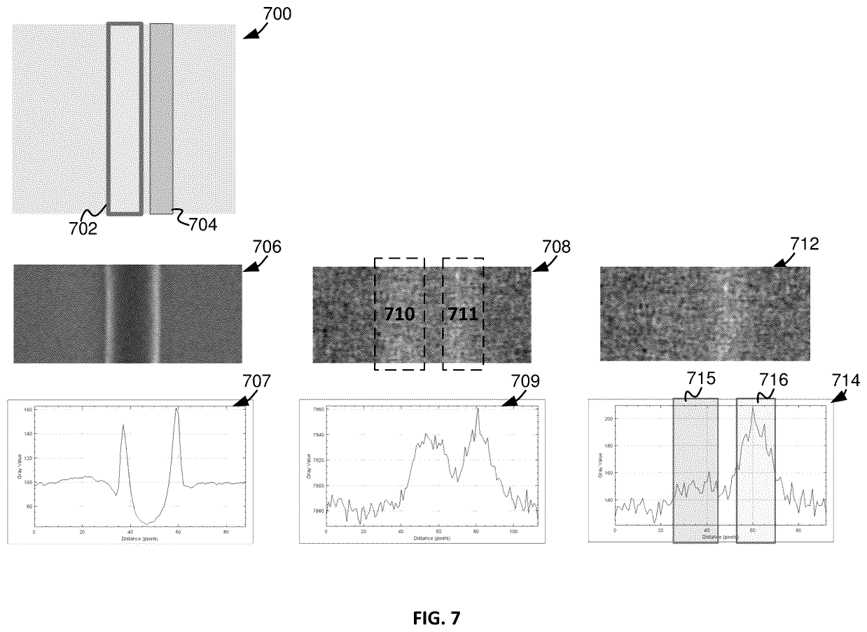

FIG. 7 shows an example of SE image and BSE image captured for a region of a specimen in accordance with certain embodiments of the presently disclosed subject matter.

The exemplified region of the specimen has a surface layer including a surface line structure, and a underlayer including a underlayer line structure. A top view 700 of the two lines structures (the surface line structure 702 and underlayer line structure 704) is presented in FIG. 7 to illustrate their relative positions in the plane of the x and y directions. A SE image 706 is acquired for the region of the specimen, presenting a representation of the surface line structure 702. As shown, the edges of the surface line structure are enhanced (e.g., the edges having brighter pixel values with respect to the interior bulk of the line structure) in the SE image 706. A gray level waveform 707 corresponding to the SE image 706 is also illustrated, where the two narrow peaks correspond to the two edges of the line structure.

A BSE image 708 is also acquired for the same region, intending to capture the underlayer line structure 704. However, the BSE image 708 captures not only a geometrical representation of the underlayer line structure 704, but also a geometrical representation of the surface line structure. As shown, the bulk/geometry of the two line structures are both visible (to some extent due to image noises) in the BSE image 708, as represented in the areas marked by dashed squares 710 and 711. The BSE image 708 does not show apparent representation of the edges. A gray level waveform 709 corresponding to the BSE image 708 is also illustrated, where the two waves correspond to the two bulks of the two line structures. As shown, the impact of the surface line structure in the BSE image is substantial (e.g., the signal strength of the image artifacts is comparable to the signal strength of the actually intended structure), thus may affect further examination process based on the BSE image, such as, e.g., measurement, overlay, etc.

For the purpose of suppressing the image artifacts caused by the surface features, it is preferred to remove, or at least reduce the bulk representation of the surface line structure 710 from the BSE image 708. Since the SE image is a topographic/contour image where edges are enhanced, whereas the effects of the surface features on the BSE image are relative to the geometrical dimensions/bulk of the surface features, it is not possible to directly use the SE image for the BSE correction/compensation. For instance, simply superimposing the SE image on the BSE image would not remedy the artifacts caused on the BSE image.

Bearing in mind these limitations, certain embodiments of the presently disclosure propose a unique way of processing the images for BSE correction. Continuing with the description of FIG. 2, the SE image can be processed (204) (e.g., by the image processing module 104) to generate a feature mask comprising a set of segments representative of the one or more structural features on the surface layer.

Specifically, the feature mask can be generated by performing image segmentation on the SE image so as to obtain the set of segments as geometrical representation of the structural features. A structural feature used herein can refer to any original element/object of a given layer that has a geometrical shape and structure with a contour, in some cases combined with other object(s) to form a structural pattern. Image segmentation may refer to any process of partitioning an image into one or more segments representative of structural features presented in the image, whilst providing per-pixel or per-region values indicative of such segments. Image segmentation can be performed in various manners, such as, e.g., by edge detection, applying a segmentation threshold on pixel values of the SE image, based on machine learning, or based on design data (CAD), etc. The present disclosure is not limited to a specific way of performing the image segmentation.

By way of example, in some cases, a segmentation neural network can be used to perform the image segmentation on the SE image. For instance, the output of the segmentation network can be a segmentation probability map in which the value of each pixel is indicative of a predicted probability of a corresponding pixel in the image belonging to the structural features, or belonging to the background region in the image. In some cases, a binary segmentation map can be provided based on the probability map, where the value of 1 indicates that a corresponding pixel in the image belongs to the structural features, while the value of 0 indicates a background pixel in the image. In cases where there are different types of structural features in one image, it is possible to assign different segments to represent the different types of features.

The term “a set of segments” can in some cases be interpreted to refer to one segment representing the structural features, or two segments if counting the background section as the second segment, or in some other cases refer to multiple segments corresponding to different types of features on the surface layer.

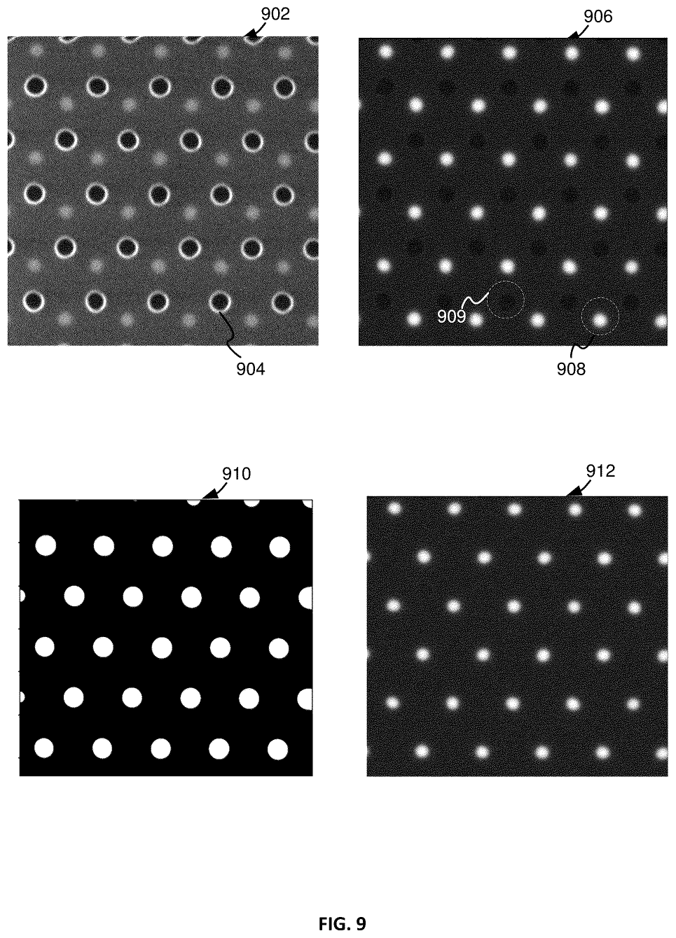

In the example of FIG. 7, the feature mask of the SE image 706, as resulting from image segmentation, would include one segment representing the surface line structure 702, while the remaining segment represents the background section. FIG. 9 illustrates an example of a feature mask 910 corresponding to a SE image 902. By way of example, in cases where there is no overlap between the surface feature and the underlayer feature, the feature mask can be a binary mask. In such cases, the value of 1 indicates the presence of a surface structural feature, whereas the value of 0 indicates the background area without any feature.

In some cases, the feature mask may also be further manipulated in various ways. For instance, the feature mask can be smoothed out using various smoothing functions, resulting in values between 0 and 1 near the geometrical edges. This can be used to correct 2^{nd} order geometrical effects at the edges of the features, such as in cases where the surface feature edges are not perfectly vertical but have continuous changes, and/or bottom rounding, or others.

A corrected BSE image can be generated (206) (e.g., by the image processing module 104) based on the BSE image and the feature mask. In some embodiments, as illustrated in FIG. 3, the corrected BSE image can be generated by applying (302) a correction factor (e.g., A) to the feature mask to obtain a corrected feature mask, and correcting (304) the BSE image using the corrected feature mask. For instance, the corrected BSE image can be represented as, e.g., BSE_corrected=BSE−A*feature_mask. The corrected BSE image is expected to possess reduced/suppressed image artifacts caused by the structural features of the surface layer.

The correction factor can be used for the purpose of minimizing the effects of the image artifacts in the BSE image caused by the structural features of the surface layer, taking into consideration gray level contrast variations between the SE image and the BSE image. These variations can be caused by various factors, including detector-related factors such as, e.g., different gains of the SE and BSE detectors, and physical factors which affect the crosstalk phenomenon, such as, e.g., landing energy of the beam, geometrical properties of the surface features (e.g., height of these features), and the depth of the underlayer, etc. In some cases, the correction factor can be correlated/associated with the signal strength of the image artifacts in the BSE image.

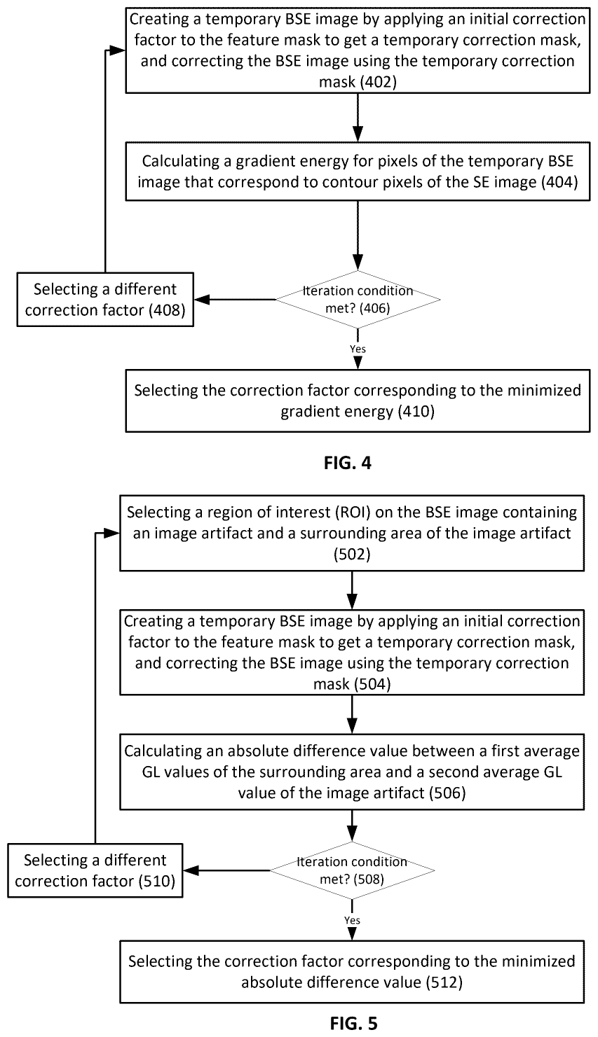

The correction factor can be derived in various ways. For instance, it can be selected manually by a user, or automatically via an optimization process. FIG. 4 illustrates a generalized flowchart of one way of automatically selecting the correction factor using an optimization process in accordance with certain embodiments of the presently disclosed subject matter.

A temporary BSE image can be created (402) using an initial correction factor. Specifically, the initial correction factor (e.g., a) can be applied to the feature mask to get a temporary correction mask. The BSE image can be corrected using the temporary correction mask, to obtain the temporary BSE image. For instance, the temporary BSE image can be represented as, e.g., BSE_tmp=BSE−a*feature_mask. The initial correction factor can be a default factor based on previous experience, or alternatively it can be selected randomly, or through electron-wafer interaction simulation.

A gradient energy can be calculated (404) for pixels of the temporary BSE image that correspond to contour pixels of the SE image. The gradient energy is with respect to the image artifacts caused by the crosstalk, corresponding to the initial correction factor. Specifically, in some cases, the gradient energy can be calculated in the following process.

First, a binary mask can be generated based on the SE image, which represents contours of the structural features on the surface layer. The binary mask can be generated, e.g., by edge detection, etc. For instance, a value of one in the binary mask represents a contour pixel in the SE image. Then, absolute gradients can be calculated for pixels of the temporary BSE image that correspond to pixels of the contours in the binary mask (e.g., pixels having a value of one in the binary mask). A gradient, or image gradient, refers to a directional change in the intensity of an image. A gradient of a given pixel can be calculated, e.g., based on the derivatives of pixel value changes at different directions of the given pixel in the image. The absolute gradients can be then aggregated to obtain a gradient energy corresponding to the initial correction factor (i.e., the gradient energy derived under the initial correction factor).

It can be verified whether an iteration condition is met (406). The iteration condition may relate to, e.g., the level of minimal gradient energy that is achieved, and/or the number of iterations, or the sizes of steps normalized with respect to the value of the current best correction factor (the factor through which the crosstalk is minimized), etc. If it is not met, a different correction factor can then be selected (408), and the creation of the temporary BSE image and the calculation of the gradient energy can be repeated using the different correction factor. This process can be iterated until the iteration condition is met. The different correction factor of each iteration can be selected in various manners, such as, e.g., a change of a given step in a direction related to the direction of the change in gradient energy from the previous iteration. The amplitude of the step can be reduced after a few iterations when a certain criterion is met, e.g., the amplitude can be reduced by a factor if the previous step passes a minimum of the absolute gradient energy with respect to the correction factor. Alternatively, in some other cases, the correction factor can be selected by way of known methods, such as, e.g., Runge-Kutta, etc.

The correction factor that corresponds to the minimized gradient energy can be selected (410) as the one to be used for the image correction. The selected correction factor, when being used, is expected to result in suppressed image artifacts in the BSE image. In fact, the selected correction factor can result in the least apparent image artifacts in the BSE image (the least image artifacts at least among the trials within the number of iterations).

Alternative to the above exemplified process, there are other ways to select the correction factor. FIG. 5 illustrates a generalized flowchart of another way of automatically selecting the correction factor in accordance with certain embodiments of the presently disclosed subject matter.

A region of interest (ROI) can be selected (502) on the BSE image containing an image artifact (e.g., an artifact caused by a surface structural feature) and a surrounding area of the image artifact. The surrounding area should not include any structural feature of the under layer. For instance, a bounding box (e.g., a rectangle) can be marked on the BSE image, containing one of the image artifacts caused by a surface structural feature, and a uniform area around it.

Similarly as described above with reference to block 402 of FIG. 4, a temporary BSE image can be created (504) by applying an initial correction factor (e.g., a) to the feature mask to obtain a temporary correction mask, and correcting the BSE image using the temporary correction mask. Based on the temporary BSE image, a first average gray level (GL) value can be calculated for pixels in the surrounding area (i.e., where the corresponding pixels in the feature mask have a value of 0), and a second average GL value can be calculated for pixels belonging to the image artifact (i.e., where the corresponding pixels in the feature mask have a value of 1). An absolute difference value between the first and second average GL values can be computed (506). The absolute difference value is derived using the initial correction factor.

Similarly as described above in FIG. 4, it can be verified whether an iteration condition is met (508). The iteration condition may relate to, e.g., the level of minimal gradient energy that is achieved, and/or the number of iterations, etc. If it is not met, a different correction factor can then be selected (510), and the creation of the temporary BSE image, the calculation of the two average GL values, and the computation of the absolute difference value can be repeated using the different correction factor. This process can be iterated until the iteration condition is met.

The correction factor that corresponds to the minimized absolute difference value can be selected (512) as the one to be used for the image correction. The selected correction factor, when being used, is expected to result in suppressed image artifacts in the BSE image. In fact, the selected correction factor can cause the image artifact to have a similar gray level as the surrounding area, thus resulting in the least apparent image artifacts in the BSE image.

Using the above-described methodology, a corrected BSE image possessing suppressed image artifacts can be generated. An example of a corrected BSE image 712 is illustrated in FIG. 7. As shown, the effect of the image artifact (e.g., the bulk representation 710 of the surface line structure 702 in the BSE image) is reduced to an extent in the corrected image, leaving the signal of the underlayer line structure 711 intact. A gray level waveform 714 corresponding to the corrected BSE image 712 is also illustrated. As shown, the impact of the surface line structure in the BSE image is significantly reduced (e.g., the signal strength 715 of the image artifact is much lower compared to the signal strength 716 of the underlayer structure).

According to certain embodiments, in some cases, the surface layer may comprise multiple types of structural features. By way of example, in addition to the surface line structures as illustrated in FIGS. 6 and 7, the surface layer may also comprise other types of line structures, such as, e.g., contact structures, etc. The multiple types of structural features may differ by design, in terms of, e.g., shape, dimensions, and/or functionalities, etc.

In such cases, the SE image can be processed to generate multiple feature masks corresponding to the multiple types of structural features. The feature mask for each type of structural features can be generated in a similar manner as described above with reference to block 204. A corrected BSE image can be generated by applying respective correction factors (e.g., A1, A2, etc.) to the multiple feature masks to obtain multiple corrected feature masks, and correcting the BSE image using the multiple corrected feature masks.

By way of example, in cases where the surface layer comprises two types of structural features, such as a line structure and a contact structure, feature_mask1 and feature_mask2 can be respectively generated for the two types of features. Two correction factors A1 and A2 can be respectively applied to the two feature masks. Each of A1 and A2 can be derived in a similar manner as described above with reference to FIGS. 4 and 5. The corrected BSE image in such cases can be represented as, e.g., BSE_corrected=BSE−A1*feature_mask1−A2*feature_mask2.

In some embodiments, the specimen may comprise multiple under layers at different depths. Each under layer comprises respective structural features. Due to the nature of the BSE emission, the BSE image can capture structural features from all multiple under layers. In such cases, the corrected BSE image can be generated by dividing the BSE image into different regions based on the structural features from different underlayers, applying different correction factors for regions in the feature mask corresponding to the different regions in the BSE image, so as to obtain the corrected feature mask, and correcting the BSE image using the corrected feature mask.

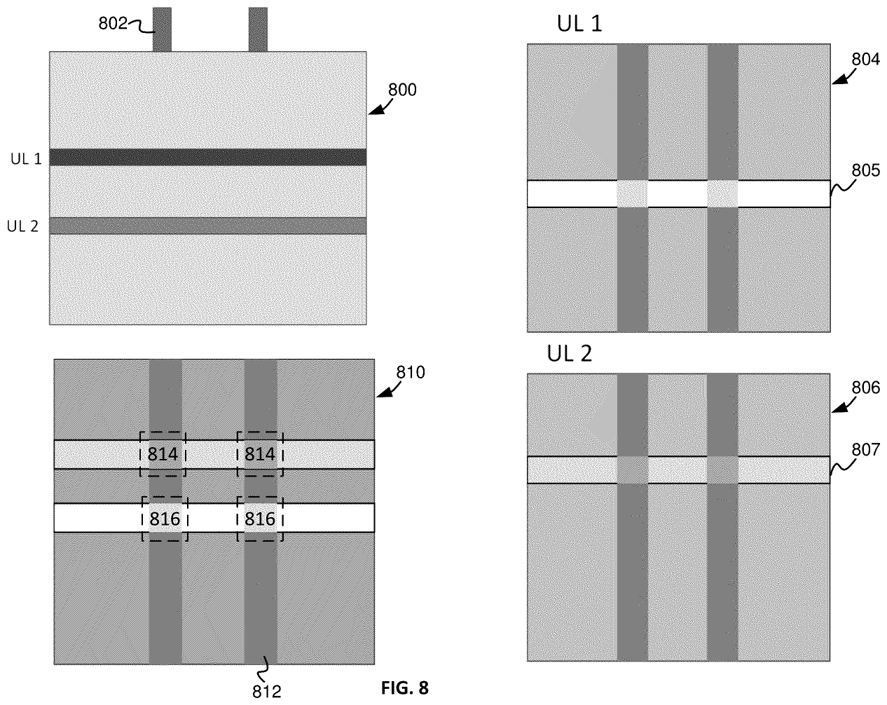

FIG. 8 illustrates an example of a specimen comprising a surface layer and two underlayers, and a corresponding BSE image in accordance with certain embodiments of the presently disclosed subject matter.

As shown in a cross-sectional view 800, the exemplified specimen comprises a surface layer where two surface line structures 802 are illustrated, as well as two underlayers, the first underlayer as an intermediate layer, marked as UL 1, and the second underlayer as a bottom layer, marked as UL 2 in the figure. A top view 804 of the UL 1 and a top view 806 of the UL 2 are also illustrated. A line structure 805 is present on UL 1 and a line structure 807 is present on UL 2. A BSE image 810 acquired for the specimen shows representation of both line structure 805 and line structure 807, as well as image artifacts 812 caused by the surface line structures 802.

In such cases, for purpose of suppressing the image artifacts 812 caused by the surface line structures in the BSE image 810, the BSE image 810 can be divided into different regions based on the structural features from different underlayers. For instance, in the overlapping region 814 where UL 2 and the image artifacts 812 of the surface line structures 802 overlap, a correction factor A1 can be applied to the corresponding region of the feature mask, whereas in the overlapping region 816 where UL 1 and the image artifacts 812 overlap, a correction factor A2 can be applied to the corresponding region of the feature mask. For the remaining regions of the image artifacts 812, another correction factor A3 can be applied to the corresponding region of the feature mask. In such cases, different correction factors A1-A3 are applied for different regions in the feature mask that correspond to the different regions 814, 816 and the remaining region in the BSE image, so as to obtain a corrected feature mask. The BSE image can be corrected using the corrected feature mask.

In some cases, both multiple underlayers and multiple types of surface structural features are present in the specimen. In such cases, both multiple feature masks corresponding to the multiple types of structural features, and multiple correction factors corresponding to different regions can be used for generating the corrected BSE image.

FIG. 9 illustrates another example of a SE image, a BSE image and a corrected BSE image in accordance with certain embodiments of the presently disclosed subject matter.

The exemplified SE image 902 shows surface structural features 904 of a surface layer, of which the edges are enhanced. The BSE image 906 shows underlayer structural features 908 of a under layer in its geometrical representation. The image artifacts 909 caused by the surface structural features 904 are also visible in the BSE image 906. Using the above-described image correction methodology, a feature mask 910 can be created, corresponding to the SE image 902, and a corrected BSE image 912 can be generated based on the BSE image 906 and the feature mask 910. The corrected BSE image 912 possesses significantly reduced image artifacts as compared to the original BSE image 906.

The corrected BSE image can be used for performing additional examination of the specimen, such as examination related to metrology operations, e.g., CD measurements, overlay, etc.

It is to be noted that examples illustrated in the present disclosure, such as, e.g., the exemplified specimen, layers, and structural features, the optimization process for selecting the correction factor, the different ways of image segmentation, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein, is providing a unique solution for a specific crosstalk phenomenon between different layers of a specimen, where the BSE emission is affected by surface patterns, causing the surface patterns to be visible on a BSE image. The image artifacts caused as such may affect further examination processes, such as, e.g., measurement, overlay, etc., on the BSE image.

In particular, since the SE image is a topographic image where edges are enhanced, whereas the BSE image is a geometrical image where the effects of the surface features on the BSE image are relative to the geometrical dimensions/bulk of the surface features, it is not possible to directly use the SE image for the BSE correction/compensation, e.g., by image superimposition.

The image correction system disclosed herein proposes to generate a feature mask of the SE image by performing image segmentation on the SE image so as to obtain a set of segments as geometrical representation of the surface structural features. This enables to convert an edge-enhanced image (i.e., the SE image) to a geometrical type of image (i.e., the feature mask) which can be used for correcting the BSE image which is of the same type/nature of images.

Among further advantages of certain embodiments of the presently disclosed subject matter as described herein, is that the corrected BSE image is generated by applying a correction factor to the feature mask to obtain a corrected feature mask, and correcting the BSE image using the corrected feature mask. The correction factor is used for the purpose of minimizing the effects of the image artifacts in the BSE image caused by the structural features of the surface layer, taking into consideration gray level variations between the SE image and the BSE image.

The image correction system proposes a few ways to automatically select the right correction factor, which, when being used, can minimize the effects of the image artifacts in the BSE image, thus further improving the image quality of the corrected BSE image.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “processing”, “using”, “generating”, “performing”, “applying”, “correcting”, “minimizing”, “creating”, “calculating”, “iterating”, “aggregating”, “computing”, “dividing”, “pre-processing”, or the like, refer to the action(s) and/or process(es) of a computer that manipulate and/or transform data into other data, said data represented as physical, such as electronic, quantities and/or said data representing the physical objects. The term “computer” should be expansively construed to cover any kind of hardware-based electronic device with data processing capabilities including, by way of non-limiting example, the examination system, the image correction system, and respective parts thereof disclosed in the present application.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of examination of a semiconductor specimen, the semiconductor specimen comprising at least a surface layer and a under layer, the system comprising a processing circuitry configured to:
obtain a secondary electron (SE) image and a backscattered electron (BSE) image of the specimen acquired by an electron beam tool, wherein the BSE image possesses one or more image artifacts caused by one or more structural features on the surface layer;
process the SE image to generate a feature mask comprising a set of segments representative of the one or more structural features; and
generate a corrected BSE image based on the BSE image and the feature mask, wherein the corrected BSE image possesses suppressed image artifacts with respect to the one or more image artifacts in the BSE image.

2. The computerized system according to claim 1, wherein the processing circuitry is configured to generate the corrected BSE image by applying a correction factor to the feature mask to obtain a corrected feature mask, and correcting the BSE image using the corrected feature mask.

3. The computerized system according to claim 2, wherein the correction factor is used for minimizing effects of the one or more image artifacts in the BSE image, taking into consideration gray level variations between the SE image and the BSE image.

4. The computerized system according to claim 1, wherein the SE image is a topographic image where contours of the structural features on the surface layer are enhanced, and wherein the feature mask is generated by performing image segmentation on the SE image so as to obtain the set of segments as geometrical representation of the structural features.

5. The computerized system according to claim 4, wherein the image segmentation is performed based on one of the following: edge detection, machine learning, a segmentation threshold for the SE image, or design data of the specimen.

6. The computerized system according to claim 2, wherein the correction factor is automatically selected by:
creating a temporary BSE image by applying an initial correction factor to the feature mask to get a temporary correction mask, and correcting the BSE image using the temporary correction mask;
calculating a gradient energy for pixels of the temporary BSE image that correspond to contour pixels of the SE image, and
iterating the creating and calculating with a different correction factor until an iteration condition is met, and selecting the correction factor having minimized gradient energy, wherein the selected correction factor, when being used, is expected to result in the suppressed image artifacts in the BSE image.

7. The computerized system according to claim 6, wherein the calculating a gradient energy comprises:
generating a binary mask based on the SE image, the binary mask representing contours of the structural features on the surface layer;
calculating absolute gradients for pixels of the temporary BSE image that correspond to pixels of the contours in the binary mask; and
aggregating the absolute gradients to obtain a gradient energy corresponding to the initial correction factor.

8. The computerized system according to claim 2, wherein the correction factor is automatically selected by:
selecting a region of interest (ROI) on the BSE image containing an image artifact and a surrounding area of the image artifact, the surrounding area not including any structural feature of the under layer;
creating a temporary BSE image by applying an initial correction factor to the feature mask to get a temporary correction mask, and correcting the BSE image using the temporary correction mask;
calculating, based on the temporary BSE image, a first average gray level (GL) value for pixels in the surrounding area and a second average GL value for pixels belonging to the image artifact;
computing an absolute difference value between the first and second average GL values, the absolute difference value corresponding to the initial correction factor; and
iterating the creating, calculating and computing with a different correction factor until an iteration condition is met, and selecting the correction factor that corresponds to a minimized absolute difference value, wherein the selected correction factor, when being used, is expected to result in the suppressed image artifacts in the BSE image.

9. The computerized system according to claim 1, wherein the surface layer comprises multiple types of structural features, and wherein the processing circuitry is configured to process the SE image to generate multiple feature masks corresponding to the multiple types of structural features, and generate the corrected BSE image by applying respective correction factors to the multiple feature masks to obtain multiple corrected feature masks, and correcting the BSE image using the multiple corrected feature masks.

10. The computerized system according to claim 1, wherein the specimen comprises multiple under layers at different depths, each under layer comprising respective structural features captured by the BSE image, and wherein the processing circuitry is configured to generate the corrected BSE image by dividing the BSE image into different regions based on the structural features from different under layers, applying different correction factors for regions in the feature mask corresponding to the different regions in the BSE image, so as to obtain the corrected feature mask; and correcting the BSE image using the corrected feature mask.

11. A computerized method of examination of a semiconductor specimen, the semiconductor specimen comprising at least a surface layer and a under layer, the method comprising:
obtaining a secondary electron (SE) image and a backscattered electron (BSE) image of the specimen acquired by an electron beam tool, wherein the BSE image possesses one or more image artifacts caused by one or more structural features on the surface layer;
processing the SE image to generate a feature mask comprising a set of segments representative of the one or more structural features; and
generating a corrected BSE image based on the BSE image and the feature mask, wherein the corrected BSE image possesses suppressed image artifacts with respect to the one or more image artifacts in the BSE image.

12. The computerized method according to claim 11, wherein the generating the corrected BSE image comprises applying a correction factor to the feature mask to obtain a corrected feature mask, and correcting the BSE image using the corrected feature mask.

13. The computerized method according to claim 12, wherein the correction factor is used for minimizing effects of the one or more image artifacts in the BSE image, taking into consideration gray level variations between the SE image and the BSE image.

14. The computerized method according to claim 11, wherein the SE image is a topographic image where contours of the structural features on the surface layer are enhanced, and wherein the feature mask is generated by performing image segmentation on the SE image so as to obtain the set of segments as geometrical representation of the structural features.

15. The computerized method according to claim 12, wherein the correction factor is automatically selected by:
creating a temporary BSE image by applying an initial correction factor to the feature mask to get a temporary correction mask, and correcting the BSE image using the temporary correction mask;
calculating a gradient energy for pixels of the temporary BSE image that correspond to contour pixels of the SE image, and
iterating the creating and calculating with a different correction factor until an iteration condition is met, and selecting the correction factor having minimized gradient energy, wherein the selected correction factor, when being used, is expected to result in the suppressed image artifacts in the BSE image.

16. The computerized method according to claim 15, wherein the calculating a gradient energy comprises:
generating a binary mask based on the SE image, the binary mask representing contours of the structural features on the surface layer;
calculating absolute gradients for pixels of the temporary BSE image that correspond to pixels of the contours in the binary mask; and
aggregating the absolute gradients to obtain a gradient energy corresponding to the initial correction factor.

17. The computerized method according to claim 12, wherein the correction factor is automatically selected by:
selecting a region of interest (ROI) on the BSE image containing an image artifact and a surrounding area of the image artifact, the surrounding area not including any structural feature of the under layer;
creating a temporary BSE image by applying an initial correction factor to the feature mask to get a temporary correction mask, and correcting the BSE image using the temporary correction mask;
calculating, based on the temporary BSE image, a first average gray level (GL) value for pixels in the surrounding area and a second average GL value for pixels belonging to the image artifact;
computing an absolute difference value between the first and second average GL values, the absolute difference value corresponding to the initial correction factor; and
iterating the creating, calculating, and computing with a different correction factor until an iteration condition is met, and selecting the correction factor that corresponds to a minimized absolute difference value, wherein the selected correction factor, when being used, is expected to result in the suppressed image artifacts in the BSE image.

18. The computerized method according to claim 11, wherein the surface layer comprises multiple types of structural features, and wherein the processing the SE image comprises processing the SE image to generate multiple feature masks corresponding to the multiple types of structural features, and generating the corrected BSE image by applying respective correction factors to the multiple feature masks to obtain multiple corrected feature masks, and correcting the BSE image using the multiple corrected feature masks.

19. The computerized method according to claim 11, wherein the specimen comprises multiple under layers at different depths, each under layer comprising respective structural features captured by the BSE image, and wherein the generating the corrected BSE image comprises dividing the BSE image into different regions based on the structural features from different under layers, applying different correction factors for regions in the feature mask corresponding to the different regions in the BSE image, so as to obtain the corrected feature mask; and correcting the BSE image using the corrected feature mask.

20. A non-transitory computer readable storage medium tangibly embodying a program of instructions that, when executed by a computer, cause the computer to perform a method of examination of a semiconductor specimen, the semiconductor specimen comprising at least a surface layer and a under layer, the method comprising:
obtaining a secondary electron (SE) image and a backscattered electron (BSE) image of the specimen acquired by an electron beam tool, wherein the BSE image possesses one or more image artifacts caused by one or more structural features on the surface layer;
processing the SE image to generate a feature mask comprising a set of segments representative of the one or more structural features; and
generating a corrected BSE image based on the BSE image and the feature mask, wherein the corrected BSE image possesses suppressed image artifacts with respect to the one or more image artifacts in the BSE image.
